(19) United States
(12) Patent Application Publication
(10) Pub. No.: US 2025/0261567 A1
(43) Pub. Date: Aug. 14, 2025

(54) MATERIAL STACK WITH IMPROVED DEVICE PERFORMANCE IN PERPENDICULARLY MAGNETIZED HEUSLER FILMS

(71) Applicants: International Business Machines Corporation, Armonk, NY (US); Samsung Electronics Co., Ltd., Gyeonggi-Do (KR)

(72) Inventors: Chirag Garg, San Jose, CA (US); Panagiotis Charilaos Filippou, Fremont, CA (US); See-Hun Yang, Morgan Hill, CA (US); Fnu Ikhtiar, San Jose, CA (US); Jaewoo Jeong, Los Altos, CA (US); Mahesh Samant, San Jose, CA (US)

(21) Appl. No.: 18/437,218

(22) Filed: Feb. 8, 2024

(51) Int. Cl. H10N 50/85; H10B 61/00; H10N 50/10

(52) U.S. Cl. CPC H10N 50/85; H10B 61/22; H10N 50/10

(57) ABSTRACT

A magnetoresistive random-access memory cell includes a substrate; a seed layer outward of the substrate; a resistive layer outward of the seed layer; and an ultra-thin templating layer. The ultra-thin templating layer is outward of the resistive layer, and includes a binary alloy having an alternating layer lattice structure. The ultra-thin templating layer has a thickness of 7-30 Angstroms. A Heusler layer is located outward of the ultra-thin templating layer, includes a Heusler compound, and exhibits perpendicular magnetic anisotropy (PMA).

### BACKGROUND

The present invention relates generally to the electrical, electronic and computer arts and, more particularly, to magnetoresistive random-access memory (MRAM).

Current MRAM devices use a magnetic tunnel junction (MTJ) as a storage element. A simple MTJ is a tri-layer structure containing two magnetic layers separated by a tunnel barrier layer. The magnetic state of one of the layers is switched using Spin Transfer Torque (STT). Thus, current MRAMs are three-layer devices employing a magnetic tunnel junction (MTJ). They typically include a reference layer magnet, a tunnel barrier, and a storage or free magnetic layer. The magnetic layer can either be a ferromagnet or a ferrimagnet. Current is passed through the device and the resistance is measured. The resistance changes based on the magnetic orientation of the two magnetic layers, and the relative change in resistance is referred to as the tunnel magnetoresistance (TMR), which is related to the spin polarization (i.e., high spin polarization implies high TMR). High spin polarization, and thus high TMR, is desirable (higher TMR provides a higher ON/OFF ratio). Low switching current is also desirable.

In a parallel configuration (e.g., storing a zero), the magnetic layers have their magnetizations aligned with each other; the resistance is typically lower in this state relative to the anti-parallel configuration (e.g., storing a one). In the anti-parallel state, the magnetic layers do not have their magnetizations aligned with each other; the resistance is typically higher in this state relative to the parallel configuration. The magnetic state of the MTJ is changed by passing a current through it. The current delivers spin angular momentum, so that once a threshold current is exceeded, the direction of the memory layer moment is switched. Since these MRAM devices are switched using STT, they are referred to as STT-MRAM. The magnitude of the switching current that is required is less when the magnetization of the electrodes is oriented perpendicular to the layers. The magnetic layers have magnetization perpendicular to the film surface (i.e. have perpendicular magnetic anisotropy (PMA)) as smaller switching currents are needed than for in-plane magnetized MTJs. MTJs with magnetic layers having PMA need smaller switching current than for in-plane magnetized layers.

Current devices employ alloys of cobalt, iron, and boron for the magnetic layers and these layers are ferromagnetic (such current devices do not scale well to smaller sizes). Heusler compounds are magnetic intermetallics with a face-centered cubic (FCC) crystal structure and a composition of X₂YZ (full-Heuslers or simply “Heuslers”), where X and Y are transition metals and Z is in the p-block (or main group) of the periodic table. Half Heuslers have the composition XYZ. Reference herein to Heusler or Heuslers without the term “half” is intended to reference full-Heuslers. Heusler compounds have four interpenetrating FCC sublattices. CoFeB devices typically need surface anisotropy for PMA, while Heusler compounds typically are PMA due to volume anisotropy.

### BRIEF SUMMARY

Principles of the invention provide interfacial nitridation for a material stack with improved device performance in perpendicularly magnetized Heusler films. In one aspect, an exemplary magnetoresistive random-access memory cell includes a substrate; a seed layer outward of the substrate; a resistive layer outward of the seed layer; and an ultra-thin templating layer, outward of the resistive layer. The ultra-thin templating layer includes a binary alloy having an alternating layer lattice structure, and has a thickness of 7-30 Angstroms. A Heusler layer is located outward of the ultra-thin templating layer, includes a Heusler compound, and exhibits perpendicular magnetic anisotropy (PMA).

In still another aspect, a magnetoresistive random-access memory array of such magnetoresistive random-access memory cells includes a plurality of bit lines and a plurality of complementary bit lines forming a plurality of bit line-complementary bit line pairs; a plurality of word lines intersecting the plurality of bit line pairs at a plurality of cell locations; and a plurality of magnetoresistive random-access memory cells located at each of the plurality of cell locations. Each of the magnetoresistive random-access memory cells is electrically connected to a corresponding bit line and selectively interconnected to a corresponding one of the complementary bit lines under control of a corresponding one of the word lines. The magnetoresistive random-access memory cells can be as described just above.

In a further aspect, a method of forming a magnetoresistive random-access memory cell includes the steps of providing a substrate; forming a nitride layer, outward of the substrate, and having a nitride layer thickness less than 20 Angstroms providing a seed layer outward of the nitride layer; and providing a resistive layer outward of the seed layer. Additional steps include providing an ultra-thin templating layer, outward of the resistive layer, and including a binary alloy having an alternating layer lattice structure; epitaxially growing a Heusler layer located outward of the ultra-thin templating layer, the Heusler layer including a Heusler compound and exhibiting perpendicular magnetic anisotropy (PMA); forming a tunnel barrier outward of the Heusler layer; and forming a magnetic layer outward of the tunnel barrier.

In yet a further aspect, a hardware description language (HDL) design structure is encoded on a machine-readable data storage medium. The HDL design structure includes elements that when processed in a computer-aided design system generate a machine-executable representation of a magnetoresistive random-access memory cell and/or array, as described.

As used herein, “facilitating” an action includes performing the action, making the action easier, helping to carry the action out, or causing the action to be performed. Thus, by way of example and not limitation, instructions executing on one processor might facilitate an action carried out by semiconductor processing equipment, by sending appropriate data or commands to cause or aid the action to be performed. Where an actor facilitates an action by other than performing the action, the action is nevertheless performed by some entity or combination of entities.

Techniques as disclosed herein can provide substantial beneficial technical effects, as will be discussed further below. Features and advantages will become apparent from the following detailed description of illustrative embodiments thereof, which is to be read in connection with the accompanying drawings.

### BRIEF DESCRIPTION OF THE DRAWINGS

The following drawings are presented by way of example only and without limitation, wherein like reference numerals (when used) indicate corresponding elements throughout the several views, and wherein:

FIG. 1 shows a Heusler compound employed in aspects of the invention;

FIG. 2 shows growth of a Heusler compound on a templating layer according to aspects of the invention;

FIGS. 3 and 4 show aspects of RA (resistance area product in Ωμm²) and TMR obtained on a sample, according to aspects of the invention;

FIG. 5 summarizes STT switching performance on various samples, according to aspects of the invention;

FIGS. 6 and 7 show additional aspects of STT switching performance, including RA (product of resistance and area) dependence, according to aspects of the invention;

FIG. 8 shows an exemplary material stack, according to an aspect of the invention;

FIG. 9 is a table showing device performance for ScₓN low damping chemical templating layer (LD-CTL) stacks with and without a nitride dusting layer, according to aspects of the invention;

FIG. 10 is a trend plot of V_{c10ns} from samples with different CoAl thickness, according to aspects of the invention;

FIG. 11 shows an exemplary MRAM cell, according to an aspect of the invention;

FIG. 12 shows an array of MRAM cells, according to an aspect of the invention;

FIG. 13 shows a flow chart of a fabrication method, according to an aspect of the invention;

FIG. 14 depicts a computing environment according to an embodiment of the present invention (e.g., for implementing a design process such as that of FIG. 15); and

FIG. 15 is a flow diagram of a design process used in semiconductor design, manufacture, and/or test.

It is to be appreciated that elements in the figures are illustrated for simplicity and clarity. Common but well-understood elements that may be useful or necessary in a commercially feasible embodiment may not be shown in order to facilitate a less hindered view of the illustrated embodiments.

### DETAILED DESCRIPTION

Principles of inventions described herein will be in the context of illustrative embodiments. Moreover, it will become apparent to those skilled in the art given the teachings herein that numerous modifications can be made to the embodiments shown that are within the scope of the claims. That is, no limitations with respect to the embodiments shown and described herein are intended or should be inferred.

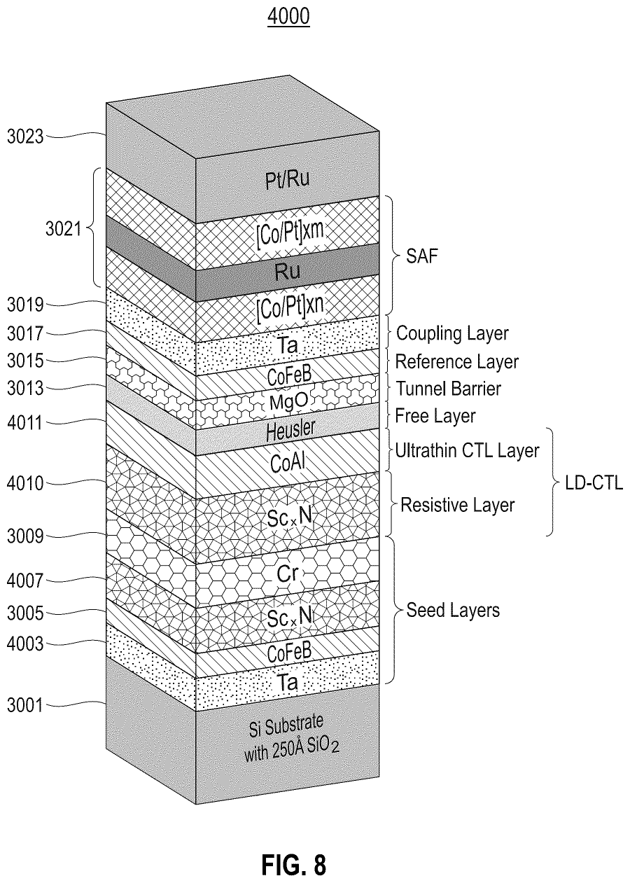

Given the discussion herein (reference characters refer to the drawings discussed below), in aspects of the invention, an exemplary magnetoresistive random-access memory cell includes a substrate 1201, 3001. Also included is a seed layer (part of 1203) outward of the substrate; in an exemplary detailed embodiment shown in FIG. 8, the seed layer includes 4003, 3005, 4007, and 3009. A resistive layer 1204B, 4010 is outward of the seed layer. An ultra-thin templating layer 1204C, 4011 is outward of the resistive layer, and includes a binary alloy having an alternating layer lattice structure. The ultra-thin templating layer has a thickness of 7-20 Angstroms or even 7-30 Angstroms. A Heusler layer 1205, 3013 is located outward of the ultra-thin templating layer. The Heusler layer includes a Heusler compound and exhibits perpendicular magnetic anisotropy (PMA). Regarding PMA, note the discussions on the time integral/average of the path of the magnetization elsewhere herein. This aspect provides the technical benefit of a simpler, and thus more desirable, material stack as compared to the prior art.

In one or more embodiments, the Heusler layer is located directly on the ultra-thin templating layer and the ultra-thin templating layer is located directly on the resistive layer. This aspect provides the technical benefit of locating the Heusler layer fairly close to the resistive layer.

One or more embodiments further include a nitride layer, outward of the substrate, and having a nitride layer thickness less than 20 Angstroms. This layer can be part of layer 1203; see 4007 shown in FIG. 8. Optionally, the nitride layer is a sub-monolayer nitride layer. This aspect provides the technical benefit of MTJ devices with better switching performance and superior magnetic properties, as compared to the prior art, from the combined incorporation of a resistive layer (e.g., ScₓN) and an interfacial nitride layer.

In one or more embodiments, the sub-monolayer nitride layer is formed with at least one of Mn, Sc, Ti, Cr, and V. This aspect provides the technical benefit of an interfacial nitride layer that reduces the number of grain boundaries and grain boundary diffusion and consequently the number of devices with intermediate steps within resistance-applied magnetic field (R-H) or resistance-voltage (R-V) loops is reduced; higher E_{B} and efficiency for lower thickness of an Mn₃Ge layer and/or reduced coefficient of variation of V_{c10ns} and free layer coercivity He are also obtained.

In some instances, the magnetoresistive random-access memory cell further includes a tunnel barrier 1209, 3015 outward of the Heusler layer; and a magnetic layer 1211, 3017 outward of the tunnel barrier. In one or more embodiments, the Heusler layer is a storage layer and the magnetic layer is a reference layer. This has the technical benefit of providing, for example, a reference layer for the cell.

In one or more embodiments, the Heusler compound is selected from the group consisting of Mn₃Ge, Mn₃Sn, Mn₃Sb, Mn₂CoSn, Mn₂FeSb, Mn₂CoAl, Mn₂CoGe, Mn₂CoSi, Mn₂CuSi, Co₂CrAl, Co₂CrSi, Co₂MnSb, and Co₂MnSi. In some instances, the Heusler compound specifically includes Mn₃Ge. This provides the technical benefit of forming the Heusler layer with available materials.

In one or more embodiments, the Heusler layer has a thickness of less than 5 nm. This contributes to the technical benefit of a compact stack.

Optionally, the tunnel barrier is in contact with the Heusler layer. The tunnel barrier can be selected from the group consisting of magnesium oxide and magnesium aluminum oxide. In some such cases, the tunnel barrier is magnesium oxide. On the other hand, in some such cases, the tunnel barrier is Mg_{1-z}Al_{2+(2/3)z}O₄, wherein −0.5<z<0.5. This has the technical benefit that the lattice spacing can be tuned (engineered) by controlling the Mg—Al composition to result in better lattice matching with the Heusler compounds.

The binary alloy can be represented by A₁₋ₓEₓ, wherein A is a transition metal element and E is a main group element including at least one of aluminum and gallium, and x is in the range from 0.42 to 0.55. Optionally, A is specifically Co and E includes Al. This aspect provides the technical benefit of being able to form the templating layer from a variety of materials.

The alternating layer lattice structure of the ultra-thin templating layer can be a cesium chloride structure. In some such instances, the ultra-thin templating layer is CoAl with a thickness of from 7 to 10 Angstroms. This aspect provides the technical benefit of, together with the resistive layer, forming a low damping chemical templating layer (LD-CTL) to minimize spin pumping.

In one or more embodiments, the resistive layer is ScₓN. The resistive layer can have a thickness of 10-250 Angstroms, or 20-100 Angstroms, for example. This aspect provides the technical benefit of an ScₓN resistive layer that reduces spin pumping, lowering the V_{c10ns} (the 50% probability to switch at a given voltage with a 10 ns pulse) while improving retention measure (E_{B}) and efficiency.

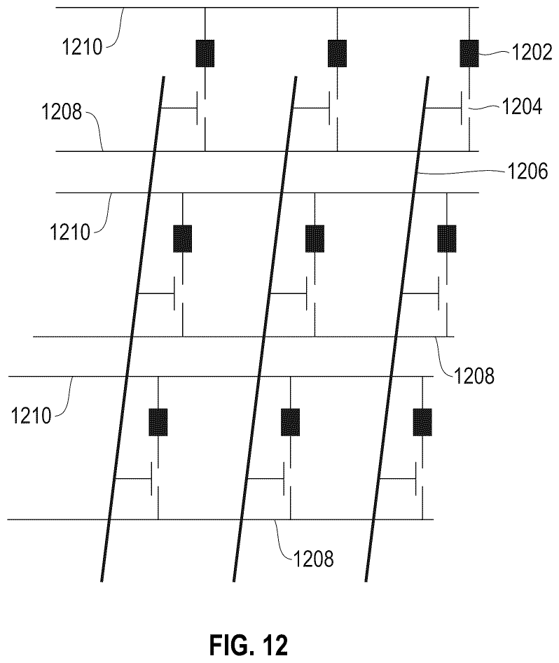

In another aspect, referring to FIG. 12, a magnetoresistive random-access memory array includes a plurality of bit lines 1210 and a plurality of complementary bit lines 1208 forming a plurality of bit line-complementary bit line pairs. A plurality of word lines 1206 intersect the plurality of bit line pairs at a plurality of cell locations. A plurality of magnetoresistive random-access memory cells 1202 are located at each of the plurality of cell locations. Each of the magnetoresistive random-access memory cells 1202 is electrically connected to a corresponding bit line 1210 and selectively interconnected to a corresponding one of the complementary bit lines 1208 under control of a corresponding one of the word lines 1206 (e.g., a respective transistor 1204 is a field effect transistor turned off or on by a signal from word line 1206 applied to its gate, which controls reading and writing and whether the cell is coupled to the complementary bit lines). This aspect provides the technical benefit of a memory array for memory applications wherein the cells can exhibit any one, some, or all of the technical benefits set forth herein.

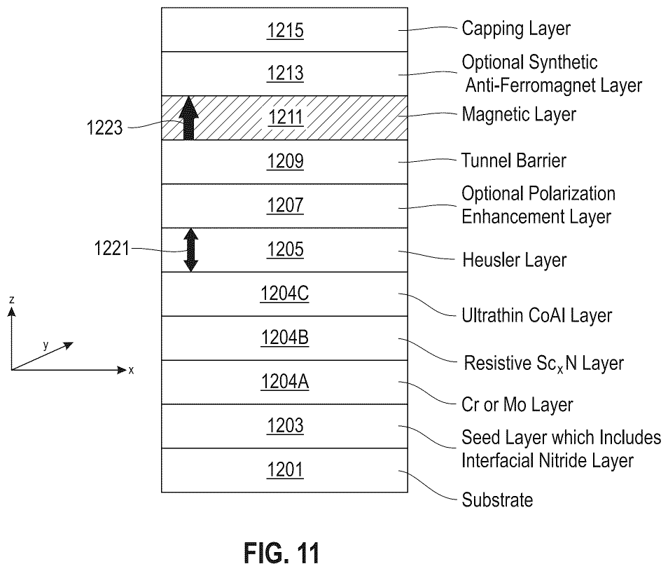

Each of the plurality of magnetoresistive random-access memory cells includes a cell as described elsewhere herein with respect to FIG. 8 and FIG. 11. Typically, the capping layer 1215 connects to the bit line 1210 while the seed layer 1203 connects to the bit line complement 1208 through the access FET. This aspect provides the technical benefit of facilitating connecting the cells into the memory array.

In still another aspect, an exemplary method of operation includes providing an array such as just described, applying signals to the word lines 1206 to cause a first subset of the cells 1202 to store logical ones and a second subset of the cells 1202 to store logical zeroes; and reading the stored logical ones and zeroes via the bit lines 1210 and the complementary bit lines 1208. This aspect provides the technical benefit of facilitating memory operations with lower switching voltage and thus reduced power consumption.

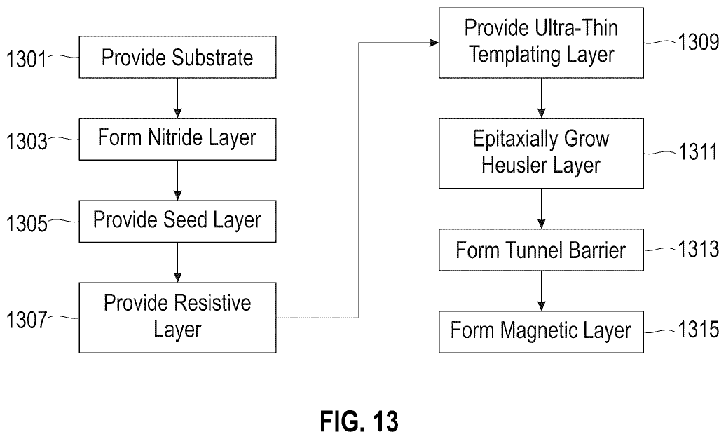

In yet another aspect, referring to FIG. 13, an exemplary method of forming a magnetoresistive random-access memory cell (such as in FIG. 8 or 11) includes, as per step 1301, providing a substrate 1201, 3001. A further step 1303 includes forming a nitride layer 4007/part of 1203, outward of the substrate, and having a nitride layer thickness less than 20 Angstroms or even less than 10 Angstroms. Still a further step 1305 includes providing a seed layer (part of 1203) outward of the nitride layer. An even further step 1307 includes providing a resistive layer 1204B, 4010 outward of the seed layer. Yet a further step 1309 includes providing an ultra-thin templating layer 1204C, 4011, outward of the resistive layer, and including a binary alloy having an alternating layer lattice structure.

Still considering the exemplary method, another step 1311 includes epitaxially growing a Heusler layer 1205, 3013 outward of the ultra-thin templating layer. The Heusler layer includes a Heusler compound and exhibits perpendicular magnetic anisotropy (PMA). A tunnel barrier 1209, 3015 is formed outward of the Heusler layer in step 1313; and a magnetic layer 1211, 3017 is formed outward of the tunnel barrier in step 1315. The method can also include providing and/or forming other elements seen in FIGS. 8 and 11 using techniques apparent to the skilled artisan, given the teachings herein. The cells can be integrated into an array by forming a plurality of cells at the same time (e.g., on the same substrate) and interconnecting them with wires, transistors, and peripheral circuitry in a manner apparent to the skilled artisan, given the teachings herein. This aspect provides the technical benefit of facilitating fabrication of a memory cell or a memory array of cells for memory applications wherein the cells can exhibit any one, some, or all of the technical benefits set forth herein.

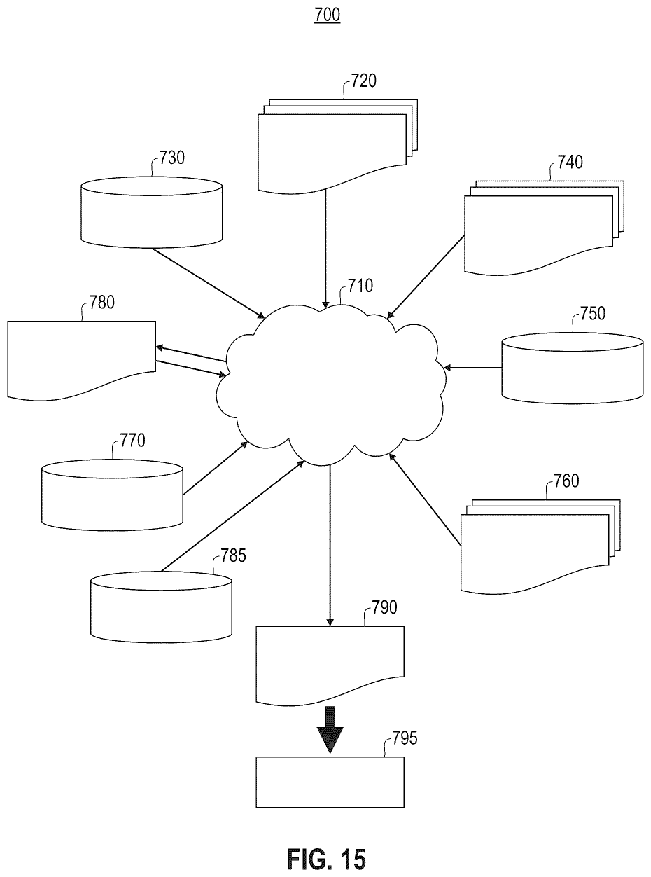

In yet a further aspect, a hardware description language (HDL) design structure is encoded on a machine-readable data storage medium. The HDL design structure includes elements that when processed in a computer-aided design system generate a machine-executable representation of a magnetoresistive random-access memory cell and/or array, as described. Refer to the discussion of FIG. 15 below. This aspect provides the technical benefit of computer-aided design and/or fabrication of a memory cell or a memory array of cells for memory applications wherein the cells can exhibit any one, some, or all of the technical benefits set forth herein.

Techniques as disclosed herein can provide substantial beneficial technical effects. Some embodiments may not have these potential advantages and these potential advantages are not necessarily required of all embodiments. By way of example only and without limitation, one or more embodiments may provide one or more of:
Combined incorporation of an ScₓN resistive layer and an interfacial nitride layer yields MTJ devices with better switching performance and superior magnetic properties as compared to the prior art;
An ScₓN resistive layer that reduces spin pumping, lowering the V_{c10ns} (the 50% probability to switch at a given voltage with a 10 ns pulse) while improving retention measure (E_{B}) and efficiency;
An interfacial nitride layer that reduces the number of grain boundaries and grain boundary diffusion and consequently the number of devices with intermediate steps within resistance-applied magnetic field (R-H) or resistance-voltage (R-V) loops is reduced; higher E_{B} and efficiency for lower thickness of an Mn₃Ge layer and/or reduced coefficient of variation of V_{c10ns} and free layer coercivity H_{c} are also obtained;
Simpler, and thus more desirable, material stack as compared to the prior art.

We have found that tetragonal Heusler compounds, which include Mn₃Z with Z═Ge, Sn, and Sb, are of interest for MRAM applications, as they exhibit PMA, have low moment due to ferrimagnetic configuration, and exhibit large anisotropy. The composition can be, for example, Mn_{3.3-x}Ge, Mn_{3.3-x}Sn, and Mn_{3.3-x}Sb, with x being in the range from 0 to not more than 1.1. Alternatively, the Heusler compound may be a ternary Heusler, e.g., Mn_{3.3-x}Co_{1.1-y}Sn, in which x≤1.2 and y≤1.0. Alternatively, the Heusler compound is chosen from Mn₂FeSb, Mn₂CoAl, Mn₂CoGe, Mn₂CoSi, Mn₂CuSi, Co₂CrAl, Co₂CrSi, Co₂MnSb, and Co₂MnSi (these compounds are listed with their nominal compositions; however, small variations (typically ≤+10%) from nominal composition of individual components within a Heusler compound should be possible). In one or more embodiments, the thickness of the Heusler storage layer in an STT-MRAM application is ultrathin (˜20 Å).

Current MRAM devices use magnetic tunnel junction (MTJ) as a storage element. A simple MTJ is a tri-layer structure containing two magnetic layers separated by tunnel barrier layer. Current MTJs using Cobalt Iron Boron (Co/Fe/B) are able to provide magnetic layers which have magnetization perpendicular to the film surface (i.e. exhibit perpendicular magnetic anisotropy (PMA), which is desirable). The perpendicular magnetic anisotropy (PMA) of Co—Fe—B layers arises from the interfaces between these layers and the tunnel barrier and/or the underlayer on which the Co—Fe—B layer is deposited. Thus, these layers should be made sufficiently thin so that the interface PMA overcomes the demagnetization energy that arises from the magnetic volume and increases in proportion with the magnetic volume of the Co—Fe—B layer. However, their high moment requires a high switching current. One or more embodiments advantageously provide PMA due to volume anisotropy but with lower magnetic moment and thus reduced switching current compared to prior art devices.

It is desirable that magnetic materials have volume PMA rather than surface (interfacial) PMA, as this enables scaling of devices to smaller sizes (typically smaller diameter). As device size is reduced, the devices become less thermally stable. However, for devices with volume anisotropy, it is advantageously possible to compensate for the lowering of thermal stability by increasing the magnetic layer thickness. The switching current is proportional to the product (Mₛ V Hₖ) where Mₛ is saturation magnetization, V is volume, and Hₖ is the anisotropy field. Low moment (i.e., low Mₛ) Heusler compounds need lower switching currents than high moment materials (such as CoFe alloys) with the same thermal energy barrier, unless the increase in Hₖ overwhelms the lower Mₛ.

Thus, for MRAM applications, it is desirable that all the magnetic elements have their moments perpendicular to the layer itself (i.e., magnetization perpendicular to the film plane-PMA arising from the crystalline structure). Low magnetization and low switching currents are desirable. Additionally, it is desirable that the MTJ devices have bistable switching states, i.e., the entire magnetic volume of the MTJ device switches between its parallel and anti-parallel states in single transitions.

Typically, Heusler compounds tend to be cubic. Thus, a thin film is grown, and the magnetic moment will be in the plane of the layer. For an MTJ for MRAM applications, it is highly desirable for the magnetic moments of the magnetic layer to be perpendicular to the layer.

One or more embodiments advantageously make Heusler compounds tetragonal with non-zero anisotropy by using an underlayer (e.g., CoAl) with a different in-plane lattice constant (as compared to the cubic form), which is itself grown on an interfacial nitride layer, obtaining volume anisotropy as opposed to interfacial anisotropy. In one or more embodiments, the Heusler material can be the bottom electrode of the MRAM cell. On the other hand, in one or more embodiments, the Heusler compound can be the top electrode of the MRAM cell. Generally, the phrase “interfacial nitride layer” can be used describe a layer with thickness of a sub-monolayer. Typically, a monolayer has a thickness of ˜2 Å and for an interfacial layer we refer to a thickness of <2 Å. Stated in an alternative manner, one or more embodiments employ sub-monolayer thick nitride.

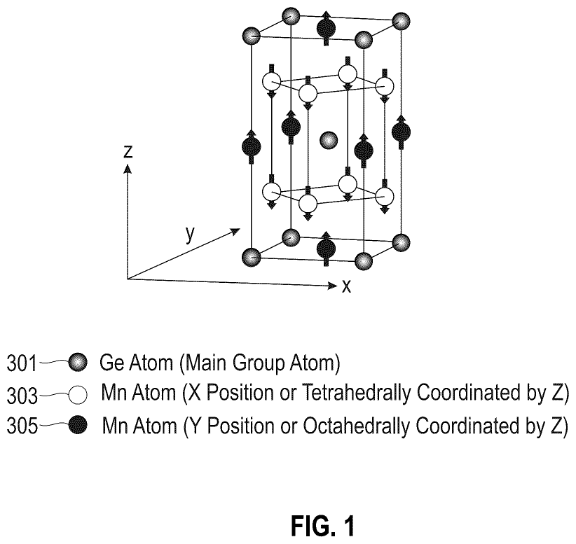

One or more embodiments make use of a templating layer (in a non-limiting example, a chemical templating layer (CTL)). Referring to FIG. 1 consider now aspects of an exemplary chemical templating layer. A Heusler compound such as Mn₃Ge (alternately Mn₃Sn or Mn₃Sb) includes alternating layers of Mn—Mn and Mn—Ge atoms. In FIG. 1, atoms with shading 301 represent Ge atoms (main group), atoms with shading 303 represent Mn atoms of the X-position in X₂YZ (tetrahedrally coordinated by Z), and atoms with shading 305 represent element Mn atoms of the Y-position in X₂YZ (octahedrally coordinated by Z). Mn is a transition metal and Ge is from the main group of the periodic table. One of the alternating layers contains transition metal atoms 303 only and other contains main group element atoms 301 along with transition metal atoms 305. Thus, a seed layer containing a single element which lattice-matches the in-plane lattice constant does not promote growth of an ordered Heusler compound at low temperatures such as room temperature. An ideal seed layer includes a binary compound of a transition element and a main group element. Moreover, this ideal seed layer also has an alternating layer structure containing these two distinct elements. One layer has only the transition metal. The other layer has only the main group element (the “Z” in X₂YZ is a main group element as well). These binary compounds have a CsCl-like (cesium chloride-like) structure (where each cesium ion is coordinated by eight chloride ions). Exemplary templating layers include CoAl, CoGa, and the like.

Referring to the crystal structure in FIG. 1, all 3 axes are not the same; dimensions a and b (not labelled in the figure, along the x and y axes) are the same in the depicted example, while dimension c (not labelled in the figure, along the vertical z axis) is different. Note the magnetization arrows going up and down along z. Stretching of crystals in the z direction yields volume anisotropy. Note the alternating layer structure. Use of a seed layer with alternating layer structure containing two distinct elements (one transition metal and other main group element) allows room-temperature ordered growth.

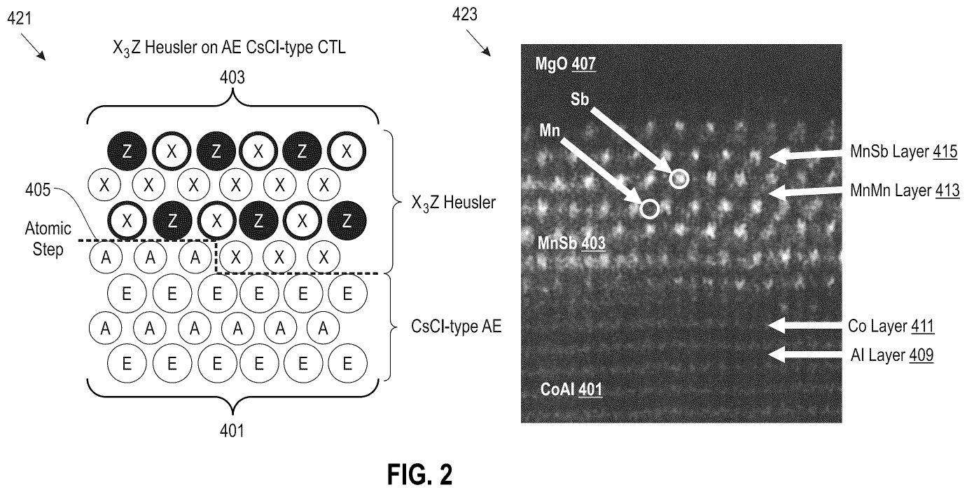

Referring now to FIG. 2, one or more embodiments employ a CsCl-type chemical templating layer (CTL) 401 (CoAl is an example of an excellent CsCl-type CTL) which promotes growth of an ordered Heusler compound even at ultrathin thicknesses and at room temperature. “E” can correspond, for example, to Al and “A” can correspond, for example, to Co. In FIG. 2, view 421 is a schematic while view 423 is a transmission electron microscopy (TEM) image. A Heusler compound such as Mn₃Ge or Mn₃Sn or Mn₃Sb 403 grows epitaxially on top of the CoAl layer 401. We have found that even ternary Heusler compounds can be ordered by the CTL. Indeed, we have found that it is pertinent in one or more embodiments that the CoAl has (001) texture, implying the requirement for a seed layer underlying the CoAl which promotes such growth. Currently, preferred seed layers include metallic MnₓN or semiconducting ScₓN which promotes the (001) texture in CoAl on Si substrates. Note, with regard to MnₓN and ScₓN, in one or more embodiments, for MnₓN 2.5≤x≤4.5 and for ScₓN 0.8≤x≤1.2.

The in-plane lattice constant of the ultrathin (<˜25 Å) Heusler compound is similar to that of the CoAl CTL. It is possible to strain the Heusler to a differing extent with an appropriate choice of CTL. We have found that even ternary Heusler compounds can be ordered by the CTL. As illustrated, the Mn (generally, X) grows on the Al and the Sb (generally, Z) grows on the Co. Note the atomic step 405. The Heusler material can be strained and thus adopts the in-plane lattice constant of the template material. One or more embodiments impose the lattice constant of the templating layer onto the Heusler layer. In view 423, note that CoAl 401 includes Al layers 409 and Co layers 411 and the Mn₃Sb 403 includes MnMn layer 413 and MnSb layer 415. Note the MgO tunnel barrier 407. The three most prominent tetragonal compounds are Mn₃Ge, Mn₃Sn, and Mn₃Sb, and Mn₃Sb has a larger difference in atomic number between Mn and Sb and thus is easier to see in the TEM image 423.

To achieve high TMR with an Mn₃Ge Heusler compound, we have found that one pertinent aspect is the use of metallic seed layers. High TMR can be achieved using metallic seed layers underlying the Heusler layer; for example, in complicated material stacks with many layers, with a purpose behind each layer. However, in at least some instances, a significant spin pumping effect increases switching voltage V_{c10ns} (the 50% probability to switch at a given voltage with a 10 ns pulse) to ˜1 V, which is too high for a practical MRAM device. Typically, there is an Si substrate and a conducting layer at the bottom to allow determination of TMR prior to device fabrication. The MTJ is only the Heusler layer, MgO tunnel barrier, and the CoFeB layer, with other layers provided to help achieve desired properties. Consider the SAF layer 3021 at the top with the small Ta coupling layer 3019 (which could also be Iridium or Ruthenium or Molybdenum); this enables making the reference layer into a pinned reference layer.

Before patterning the stack, it is desirable to know the TMR. This can be measured using a technique known as current in-plane tunneling (CIPT). To carry out CIPT, a CIPT layer (Ta or Ta/Ru/Ta) or a thick Chromium layer are employed, as well as suitable templating layers.

As noted, complex stacks may advantageously provide high TMR. However, a relatively high switching voltage on the order of 1 V is required, while half a volt or less is desirable. One or more embodiments advantageously significantly lowers this switching voltage.

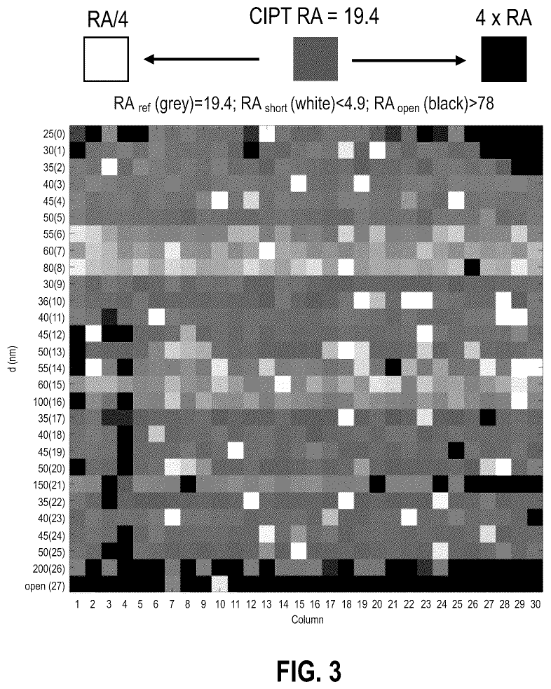

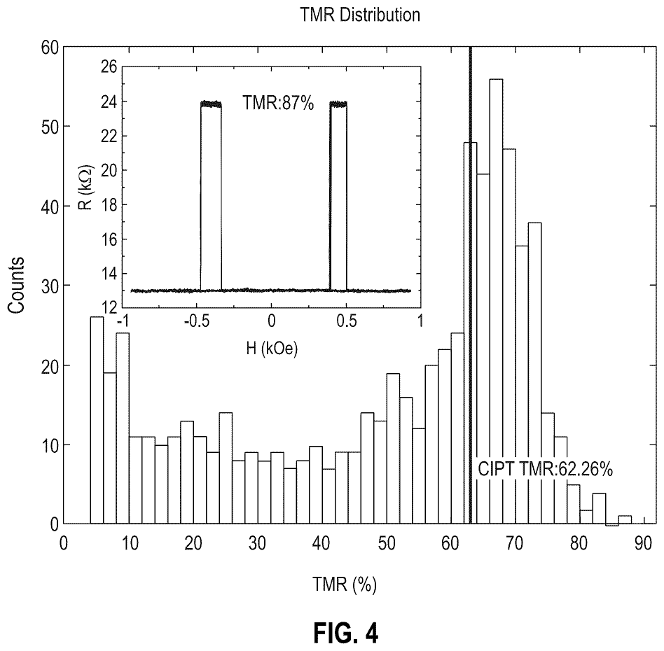

Refer now to FIGS. 3 and 4, which are presented for a sample including (all thicknesses in Angstroms (Å)) 50 Ta, 5 CoFeB20, 300 MnN, 400 Cr, 50 IrAl, 150 CoAl, 13 Mn₃Ge annealed at 342° C., 17 MgO, CoFeB, 50 Ta, and 100 Ru annealed at 375° C. The seed layer underlying the Heusler layer is metallic ˜300 Å MnₓN (or ScₓN), 400 Å Cr, 50 Å IrAl, 150 Å CoAl.

FIG. 3 shows a yield map of devices on a wafer where each square represents a MTJ device and the shading indicates the RA of the MTJ device relative to its CIPT RA. Open square indicates a shorted MTJ device (device RA<¼ of CIPT RA) while black square indicates an open MTJ device (RA>4 times CIPT RA).

FIG. 4 shows the count of devices with a given TMR percentage. It can be seen that with high CIPT TMR (over 60%), it is possible to obtain devices with TMR over 80%. While not as high as Co and B devices, this is competitive. The annealing temperaturę is nominal and is done in situ. In the example, the device RA is 12.3 Ωμm² for a nominal size of 35 nm. FIG. 4 thus shows an exemplary TMR distribution in counts versus TMR (%). A highest single device TMR of 87% and a top 10 device TMR average of 81.7% were achieved. The loop is from the device with the highest TMR.

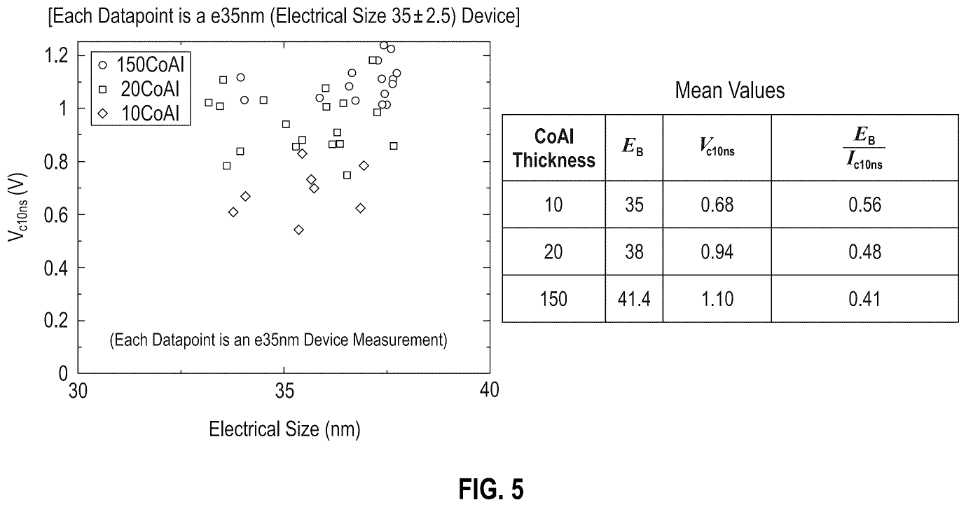

Referring now to FIG. 5, a summary of STT switching performance results, consider aspects of how to lower V_{c10ns}. The left-hand side is a plot of V_{c10ns} versus electrical size in nm. In the example, 90 Å ScN was placed on top of the Cr CIPT layer, and different thicknesses of CoAl were tested. As the thickness of the CoAl layer is lowered, V_{c10ns} drops significantly (from about 1 V to 600 mV). As seen in the table on the right-hand side of FIG. 5, mean V_{c10ns} can be lowered from 1.10 to 0.68, a bit more than 30%, by reducing the CoAl thickness. It is pertinent to note that the ScN is a semiconducting nitride, not a metallic nitride, so that there is a resistive layer very close to the Mn₃Ge Heusler layer. The presence of the resistive layer reduces the spin-pumping effect. This means that the spins being brought in to do the switching are not getting pumped into a metallic system, but rather into a semiconducting system, so that the spin is not being lost, but rather, the spins are actually acting on the Heusler layer and can more effectively switch the Heusler layer. In contrast, when there is a thick conducting layer underneath the Heusler layer, many spins are lost, and cannot carry out their function of helping in switching. It can be seen that there is an ˜40% decrease in V_{c10ns} and an ˜35% increase in switching performance for 10 Å CoAl. The 150 Angstrom CoAl, 20 Angstrom CoAl, and 10 Angstrom CoAl exemplary samples had the following respective details (in the following, “Ref” refers to an exemplary reference layer of CoFeB, 2.4 Å Ta, annealed at 232° C., SAF, 100 Å Ru, where SAF is Synthetic antiferromagnet):
50 Å Ta, 5 Å CoFeB20, 20 Å ScN, 400 Å Cr, 90 Å ScN, 150 Å CoAl, 19 Å Mn₃Ge annealed at 342° C., 15.5 Å MgO, Ref (RA: 10.5 Ωμm²)
50 Å Ta, 5 Å CoFeB20, 20 Å ScN, 400 Å Cr, 90 Å ScN, 20 Å CoAl, 17 Å Mn₃Ge annealed at 342° C., 15.5 Å MgO, Ref (RA: 11.5 Ωμm²)
50 Å Ta, 5 Å CoFeB20, 20 Å ScN, 400 Å Cr, 90 Å ScN, 10 Å CoAl, 17 Å Mn₃Ge annealed at 342° C., 15.5 Å MgO, Ref (RA: 10.5 Ωμm²).

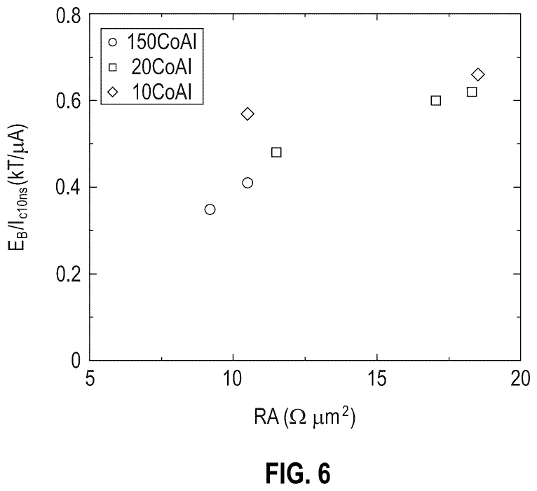

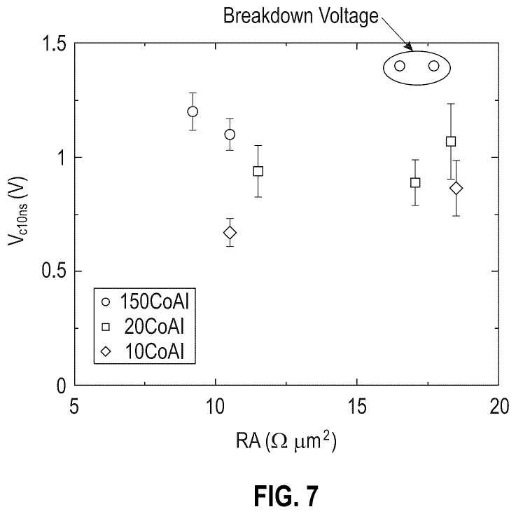

FIGS. 6 and 7 present a summary of STT switching performance results including RA dependence, for the three example stacks above. Each data point within the plot is the mean of 5 to 30 e35 nm devices. Furthermore in this regard, as used herein, an e35 nm device is a device whose diameter is 35 nm as determined by device resistance measurement (with a defined tolerance as explained shortly). The RA, which is the Resistance Area product for blanket films, is known. During survey scans, measure resistance of devices. Using RA, determine A for each measured device. The A allows the determination of device diameter. The device diameter determined by this technique is referred by suffix ‘e.’ Herein, refer to all devices with electrical size of 35±2.5 nm as e35 nm. FIG. 5 shows all devices whose electrical size is 35±2.5 nm. The table in FIG. 5 presents the mean of 5 to 30 devices. The Y-axis label for FIG. 6 is an efficiency formula. E_{B} is a retention measure. I_{c10ns} is the current which is in turn V_{c10ns} divided by the resistance of the device. If the current is reduced, the efficiency goes up.

It can be seen that both V_{c10ns} and E_{B}/I_{c10ns} are consistently better for thin CoAl for an RA range of ˜8 to 18 Ω-μm². For high RA devices, STT switching for the 150 Å CoAl sample was not possible, so breakdown voltage was plotted as the lower bound in FIG. 7. Similar performance improvements were obtained with the use of thin MgO insertion layer within CoAl templating layer in close proximity of Heusler layer on MgO substrates.

Referring now to FIG. 8, one or more embodiments employ a stack 4000 with a low damping chemical templating layer (LD-CTL) to minimize spin pumping. This effect is manifested in the damping constant. Based on the physics of the system, it is believed that the damping constant in the example of FIG. 8 is lower than in systems that do not employ the LD-CTL. In FIG. 8, the stack 4000 includes a silicon substrate 3001 with 250 Angstroms of SiO₂; a seed layer including Ta 4003, CoFeB 3005, ScₓN 4007, and Cr 3009; an ScₓN resistive layer 4010 provided in close proximity to the Heusler layer 3013 that it is desired to switch; an ultrathin CTL layer 4011; the aforementioned Heusler (free) layer 3013; an MgO tunnel barrier 3015; a CoFeB reference layer 3017; a Ta coupling layer 3019; a Synthetic anti-ferromagnet (SAF) layer 3021 including [Co/Pt]xn, Ru, and [Co/Pt]xm where n and m are number of repeats; and a Pt/Ru capping layer 3023. In FIG. 8, the resistive layer 4010 plus ultrathin CTL layer 4011, together forming the LD-CTL, yield improved performance as measured by lowered V_{c10ns} (as compared to cells not using the LD-CTL). Furthermore, efficiency is improved, as seen in FIG. 6.

Thus, the LD-CTL lowers V_{c10ns}, and can be achieved by placing the resistive ScₓN layer 4010 in contact with the ultrathin chemical templating layer 4011 (thickness on the order of 10 Å), advantageously reducing spin pumping into the metallic underlayers. In one or more embodiments, the resistive ScₓN is fairly thick, on the order of 20-100 Å or even 10-100 Å or even 10 or 20 up to 250 Å. Possible variations include, for example, a seed layer without the Cr layer 3009; a multilayer of Cr/ScₓN; annealing of the ScₓN layer prior to Mn₃Ge deposition; and/or cryocooling of the ScₓN resistive layer prior to CoAl deposition. Embodiments such as that depicted in FIG. 8 can advantageously achieve significantly lowered V_{c10ns} and improved efficiency with the LD-CTL. The overall stack thickness, in one or more embodiments, is competitive with current CoFeB-based MTJs.

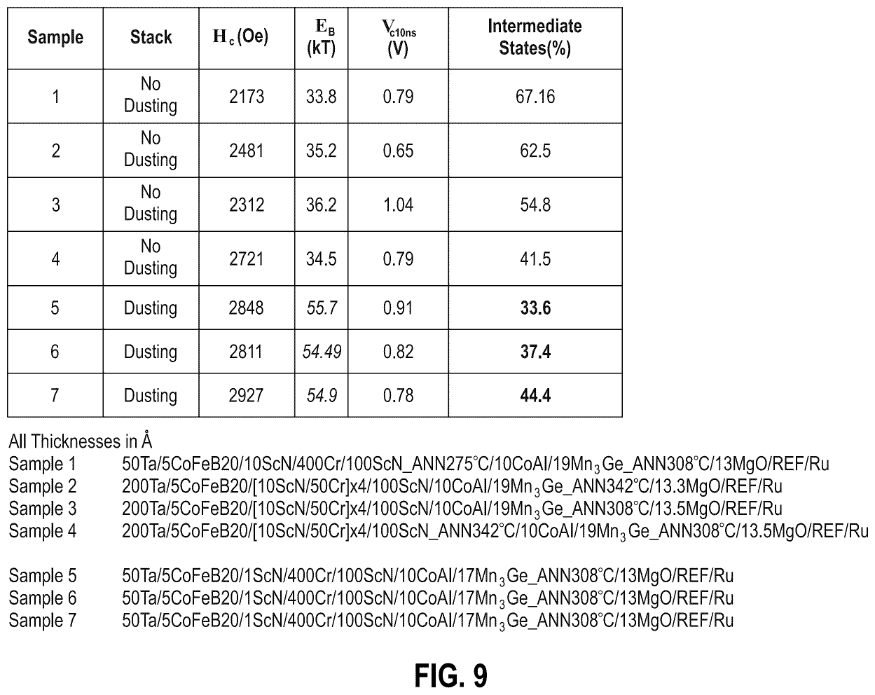

FIG. 9 is a table showing various parameters—it is desired in one or more embodiments to lower V_{c10ns} with fairly high E_{B} as in enlarged italics and a lower number of intermediate states as in enlarged bold. It can be seen that a dusting (interfacial) layer is desirable in one or more embodiments. In the description of the samples, “×4” means the layer structure in square brackets “[ ]” is repeated four times and ANN refers to annealing at the indicated temperature. Thus, for low damping chemical templating layer (LD-CTL) stacks with a nitride dusting layer, the following were consistently obtained:

Higher E_{B} (˜55 kT with 17 Å Mn₃Ge instead of ˜35 kT with 19 Å Mn₃Ge) Fewer devices with intermediate steps.

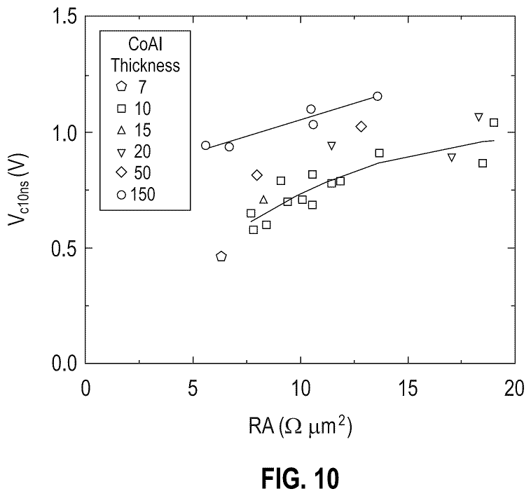

FIG. 10 is a trend plot to show V_{c10ns} for various values of RA for samples with various CoAl thicknesses. In one or more embodiments, an RA from 5 to 20 is the most interesting range for the device. For CoAl thicknesses of 7 to 50 Å, an ScₓN resistive layer is present underneath, while for CoAl thicknesses of 150 Å, there is a mix of samples—with and without the ScₓN resistive layer. V_{c10ns} depends on the CoAl thickness. Significant improvement in the V_{c10ns} is noted for an LD-CTL with 10 A CoAl chemical templating layer. An LD-CTL with 7 Å CoAl may even have a lower V_{c10ns} at low RA (E_{B} was low (˜24 kT) for this sample).

Thus, in one or more embodiments, the combined incorporation of the ScₓN resistive layer and interfacial nitride layer yields MTJ devices with better switching performance and superior magnetic properties. The ScₓN resistive layer reduces spin pumping. lowering the V_{c10ns} while improving E_{B} and efficiency. An interfacial nitride layer reduces the number of grain boundaries and grain boundary diffusion and consequently the number of devices with intermediate steps within RH or RV loops is reduced. Another advantageous consequence is higher E_{B} and efficiency for a lower thickness of the Mn₃Ge layer. Furthermore, the material stack is simpler, and thus more desirable than a complex stack.

FIG. 11 shows an exemplary embodiment with a Heusler compound as the storage layer 1205. The seed layer 1203 will typically include an interfacial nitride, and is located on substrate 1201. Substrate 1201 is typically silicon with CMOS circuitry such as transistors and access lines permitting selection of individual devices. Other than the novel cells described herein, conventional transistors, access lines, peripheral circuits, and the like can be employed-refer to discussion of FIG. 12 below. A Cr or Mo layer 1204A is located outward of the seed layer 1203, and can be thought of as part of the seed layer in some instances. The resistive ScₓN layer (1204B) is outward of the layer 1204A, and the ultrathin CoAl CTL (1204C) is outward of the resistive layer. Heusler layer 1205 is located on the CTL, and can be formed, for example, by epitaxial growth on the CTL. Polarization enhancement layer 1207 is optionally located outward of layer 1205; layer 1207, where present, can include, for example, a thin layer of magnetic material such as cobalt. Tunnel barrier 1209 is located outward of layer 1207 (where present), else outward of layer 1205; barrier 1209 can include, for example, MgO, MgAl₂O₄, or the like. Magnetic layer 1211 includes conventional cobalt, iron, nickel, or alloys, or could also include Heusler or half-Heusler materials. Synthetic anti-ferromagnet (SAF) layer 1213, where present, is located outward of layer 1211. Typically, a Synthetic Anti-Ferromagnet (SAF) layer includes a Co/Pt multilayer (not shown) that is magnetically coupled to the underlying magnetic layer to achieve needed performance. A thin layer (not shown) of Ta or Ir or Ru or Mo (order of few Å) may typically be interposed between the magnetic layer and the SAF layer. Cap layer 1215 is located outward of layer 1213 (where present), else outward of layer 1211. The cap layer may include Mo, W, Ta, Pt, Ru, or a combination thereof. In FIG. 11, double-headed arrow 1221 indicates the storage layer wherein the magnetization can be changed, while single-headed arrow 1223 indicates the reference layer with constant/fixed magnetization. We have found that it is desirable for the Heusler layer 1205 to be in close proximity to the resistive ScₓN layer 1204B; in the depicted example, they are separated only by the ultrathin templating layer 1204C above layer 1204B.

It will thus be appreciated that one or more embodiments provide a structure including a substrate 1201; an interfacial nitride layer formed with Mn, Sc, Ti, Cr, V, or the like overlying the substrate wherein this nitride layer thickness is less than 20 Angstroms or even less than 10 Å; a seed layer of Cr overlying the interfacial nitride layer; a resistive ScₓN layer 1204B; an ultrathin templating layer 1204C including a binary alloy having a CsCl structure; and a magnetic layer 1205 overlying the templating layer. The magnetic layer includes a Heusler compound whose magnetization is substantially perpendicular to the layer (aspects of perpendicularity are discussed elsewhere herein). For illustrative convenience, in FIG. 11, the seed layer and interfacial nitride layer are depicted together at 1203; exemplary details can be seen in FIG. 8.

In some instances, the Heusler compound is Mn₃Ge.

The Heusler layer can have a thickness of, for example, less than 5 nm.

In one or more embodiments, the binary alloy with CsCl structure is represented by A₁₋ₓEₓ, where A is a transition metal element and E is a main group element. For example, A includes Co and E includes at least aluminum or gallium and possibly traces of other elements (e.g., Al or Ga; or Al alloyed with Ga, Ge, Sn, or any combination thereof, such as AlSn, AlGe, AlGaGe, AlGaSn, AlGeSn, and AlGaGeSn), and x is in the range from 0.42 to 0.55.

The thickness of the CoAl layer can range, for example, from 7 to 10 Å or 7 to 15 Å or even 7 to 20 Å.

In a non-limiting example, the resistive ScₓN layer can be at least 10 Å thick; for example, 10-100 Å thick.

In some instances, the tunnel barrier 1209 is in contact with the Heusler layer 1205. The tunnel barrier can include, for example, MgO.

In some instances, the Heusler compound is selected from the group consisting of Mn₃Sn, Mn₃Sb, Mn₂CoSn, Mn₂FeSb, Mn₂CoAl, Mn₂CoGe, Mn₂CoSi, Mn₂CuSi, Co₂CrAl, Co₂CrSi, Co₂MnSb, and Co₂MnSi. In this case as well, the Heusler layer can have a thickness of, for example, less than 5 nm; and the binary alloy with CsCl structure can be represented by A₁₋ₓEₓ, as discussed above. Further, in this case as well, the thickness of the CoAl layer can range, for example, from 7 to 20 Å; in a non-limiting example, the resistive ScₓN layer can be 100 Å thick; and in some instances, the tunnel barrier 1209 is in contact with the Heusler layer 1205. The tunnel barrier can include, for example, MgO.

When for example, the tunnel barrier is in contact with the Heusler layer, MgAl₂O₄ can be used as a tunnel barrier whose lattice spacing can be tuned (engineered) by controlling the Mg—Al composition to result in better lattice matching with the Heusler compounds (e.g., the composition of this tunnel barrier can be represented as Mg_{1-z}Al_{2+(2/3)z}O₄, wherein −0.5<z<0.5). We have found that this engineering is appropriate for both the case when the Heusler compound is Mn₃Ge and the case when the Heusler compound is selected from the group consisting of Mn₃Sn, Mn₃Sb, Mn₂CoSn, Mn₂FeSb, Mn₂CoAl, Mn₂CoGe, Mn₂CoSi, Mn₂CuSi, Co₂CrAl, Co₂CrSi, Co₂MnSb, and Co₂MnSi.

As will be appreciated by the skilled artisan, typically, the magnetization is not fixed, but rather, the magnetization precesses like a spinning top at a non-zero temperature. This can change depending on temperature. In view of this precession, perpendicularity, as used herein, refers to perpendicularity of the time integral/average of the path of the magnetization. The time integral/average of the path of the magnetization could be, for example, “exactly” perpendicular, perpendicular within ±5%, or perpendicular within ±10%.

It should be noted that the Heusler compounds are indicated by stoichiometric formulas and this does not preclude small variations of up to several % from the nominal values.

Referring now to FIG. 12, an array of MRAM devices 1202 is shown. Each cell 1202 (e.g., embodiment of FIG. 11) is connected to a respective transistor 1204 that controls reading and writing. A word line 1206 provides data to write to the cells 1202, while a bit line 1210 and a bit line complement 1208 read data from the cell 1202. In this manner, a large array of memory devices can be implemented on a single chip. An arbitrarily large number of cells 1202 can be employed, within the limits of the manufacturing processes and design specifications.

Writing data to a cell 1202 includes passing a current through the cell. This current causes the direction of magnetization to switch between a parallel or anti-parallel state, which has the effect of switching between low resistance and high resistance. Because this effect can be used to represent the 1s and 0s of digital information, the cells 1202 can be used as a non-volatile memory. Passing the current in one direction through the cell 1202 causes the magnetization of the free layer 1205 to be parallel with that of the reference layer 1211, while passing the current in the other direction through the cell 1202 causes the magnetization of the free layer 1205 to be antiparallel to that of the reference layer 1211. Reading the bit stored in a cell 1202 involves applying a voltage (lower than that used for writing information) to the cell 1202 to discover whether the cell offers high resistance to current (“1”) or low resistance (“0”).

Semiconductor device manufacturing includes various steps of device patterning processes. For example, the manufacturing of a semiconductor chip may start with, for example, a plurality of CAD (computer aided design) generated device patterns, which is then followed by effort to replicate these device patterns in a substrate. The replication process may involve the use of various exposing techniques and a variety of subtractive (etching) and/or additive (deposition) material processing procedures. For example, in a photolithographic process, a layer of photo-resist material may first be applied on top of a substrate, and then be exposed selectively according to a pre-determined device pattern or patterns. Portions of the photo-resist that are exposed to light or other ionizing radiation (e.g., ultraviolet, electron beams, X-rays, etc.) may experience some changes in their solubility to certain solutions. The photo-resist may then be developed in a developer solution, thereby removing the non-irradiated (in a negative resist) or irradiated (in a positive resist) portions of the resist layer, to create a photo-resist pattern or photo-mask. The photo-resist pattern or photo-mask may subsequently be copied or transferred to the substrate underneath the photo-resist pattern.

There are numerous techniques used by those skilled in the art to remove material at various stages of creating a semiconductor structure. As used herein, these processes are referred to generically as “etching”. For example, etching includes techniques of wet etching, dry etching, chemical oxide removal (COR) etching, ion milling, and reactive ion etching (RIE), which are all known techniques to remove select material(s) when forming a semiconductor structure. The Standard Clean 1 (SC1) contains a strong base, typically ammonium hydroxide, and hydrogen peroxide. The SC2 contains a strong acid such as hydrochloric acid and hydrogen peroxide. The techniques and application of etching is well understood by those skilled in the art and, as such, a more detailed description of such processes is not presented herein.

Although the overall fabrication method, including the epitaxial growth of the Heusler material on the ultra-thin templating layer in proximity to the resistive (e.g., ScₓN) layer, and the structures formed thereby, are novel, certain individual processing steps required to implement the method may utilize conventional semiconductor fabrication techniques and conventional semiconductor fabrication tooling. These techniques and tooling will already be familiar to one having ordinary skill in the relevant arts given the teachings herein. Moreover, one or more of the processing steps and tooling used to fabricate semiconductor devices are also described in a number of readily available publications, including, for example: James D. Plummer et al., Silicon VLSI Technology: Fundamentals, Practice, and Modeling 1^{st} Edition, Prentice Hall, 2001 and P. H. Holloway et al., Handbook of Compound Semiconductors: Growth, Processing, Characterization, and Devices, Cambridge University Press, 2008, which are both hereby incorporated by reference herein. It is emphasized that while some individual processing steps are set forth herein, those steps are merely illustrative, and one skilled in the art may be familiar with several equally suitable alternatives that would be applicable.

It is to be appreciated that the various layers and/or regions shown in the accompanying figures may not be drawn to scale. Furthermore, one or more semiconductor layers of a type commonly used in such integrated circuit devices may not be explicitly shown in a given figure for ease of explanation. This does not imply that the semiconductor layer(s) not explicitly shown are omitted in the actual integrated circuit device.

As noted elsewhere, optionally, the nitride layer is a sub-monolayer nitride layer. Generally, the phrase “interfacial nitride layer” can be used describe a layer with thickness of a sub-monolayer. Typically, a monolayer has a thickness of ˜2 Å and for an interfacial layer we refer to a thickness of <2 Å. Stated in an alternative manner, one or more embodiments employ sub-monolayer thick nitride. A nitride layer is referred to as “interfacial” or “sub-monolayer” or “dusting” herein when it is not a complete nitride layer, i.e., it is not even a monolayer. When material is deposited, typically, a shutter is opened and there is a scandium target present. Argon and nitrogen are provided in the gaseous phase. During sputtering, the scandium is transferred from the target to the substrate. Some of the nitrogen atoms are incorporated into the film to form scandium nitride. A growth rate can be measured, such as growing ½ Angstrom per second. This can be determined by growing a film with a detectable thickness (say, 100 Angstroms) (measure, e.g., with a profilometer) and dividing by the time it takes to grow (say 200 seconds so ½ Angstrom per second). To grow “1 Angstrom,” keep the shutter open for 2 seconds; to grow 10 Angstroms, open for 20 seconds; etc. A thin layer, less than a monolayer, can be discontinuous (i.e., a monolayer with holes) or sparse (scandium/nitrogen reacting with or undergoing adsorption onto the layer underneath). Thus, the terminology “interfacial or dusting layer.” Note, as used herein, including the claims, a “sub-monolayer nitride layer” is intended to define a layer having a sub-monolayer thickness on average, and to include both discontinuous such layers (i.e., having local monolayer thickness and holes) and layers with reaction/adsorption.

Those skilled in the art will appreciate that the exemplary structures discussed above can be distributed in raw form (i.e., a single wafer having multiple unpackaged chips), as bare dies, in packaged form, or incorporated as parts of intermediate products or end products that benefit from a material stack with an LD-CTL and the like.

An integrated circuit in accordance with aspects of the present inventions can be employed in essentially any application and/or electronic system where a material stack with an LD-CTL and the like would be beneficial. Given the teachings of the present disclosure provided herein, one of ordinary skill in the art will be able to contemplate other implementations and applications of embodiments disclosed herein.

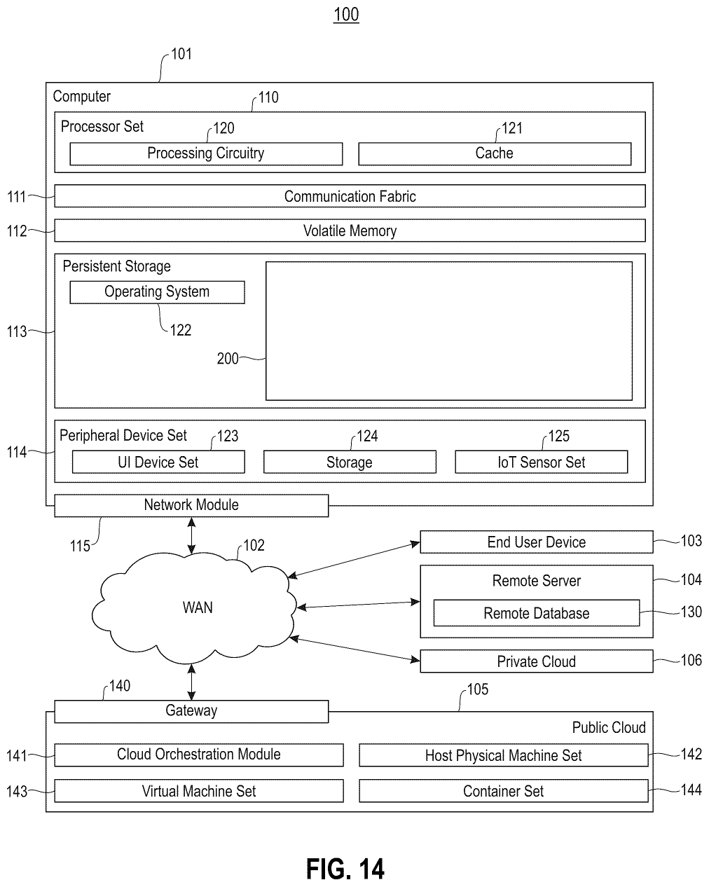

Reference should now be had to FIG. 14, which depicts a computing environment according to an embodiment of the present invention (e.g., for implementing a design process such as that of FIG. 15)

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

Computing environment 100 contains an example of an environment for the execution of at least some of the computer code involved in performing the inventive methods, such as a system 200 for semiconductor design and/or control of semiconductor fabrication (see FIG. 15). In addition to block 200, computing environment 100 includes, for example, computer 101, wide area network (WAN) 102, end user device (EUD) 103, remote server 104, public cloud 105, and private cloud 106. In this embodiment, computer 101 includes processor set 110 (including processing circuitry 120 and cache 121), communication fabric 111, volatile memory 112, persistent storage 113 (including operating system 122 and block 200, as identified above), peripheral device set 114 (including user interface (UI) device set 123, storage 124, and Internet of Things (IoT) sensor set 125), and network module 115. Remote server 104 includes remote database 130. Public cloud 105 includes gateway 140, cloud orchestration module 141, host physical machine set 142, virtual machine set 143, and container set 144.

COMPUTER 101 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 130. As is well understood in the art of computer technology, and depending upon the technology, performance of a computer-implemented method may be distributed among multiple computers and/or between multiple locations. On the other hand, in this presentation of computing environment 100, detailed discussion is focused on a single computer, specifically computer 101, to keep the presentation as simple as possible. Computer 101 may be located in a cloud, even though it is not shown in a cloud in FIG. 14. On the other hand, computer 101 is not required to be in a cloud except to any extent as may be affirmatively indicated.

PROCESSOR SET 110 includes one, or more, computer processors of any type now known or to be developed in the future. Processing circuitry 120 may be distributed over multiple packages, for example, multiple, coordinated integrated circuit chips. Processing circuitry 120 may implement multiple processor threads and/or multiple processor cores. Cache 121 is memory that is located in the processor chip package(s) and is typically used for data or code that should be available for rapid access by the threads or cores running on processor set 110. Cache memories are typically organized into multiple levels depending upon relative proximity to the processing circuitry. Alternatively, some, or all, of the cache for the processor set may be located “off chip.” In some computing environments, processor set 110 may be designed for working with qubits and performing quantum computing.

Computer readable program instructions are typically loaded onto computer 101 to cause a series of operational steps to be performed by processor set 110 of computer 101 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 121 and the other storage media discussed below. The program instructions, and associated data, are accessed by processor set 110 to control and direct performance of the inventive methods. In computing environment 100, at least some of the instructions for performing the inventive methods may be stored in block 200 in persistent storage 113.

COMMUNICATION FABRIC 111 is the signal conduction path that allows the various components of computer 101 to communicate with each other. Typically, this fabric is made of switches and electrically conductive paths, such as the switches and electrically conductive paths that make up busses, bridges, physical input/output ports and the like. Other types of signal communication paths may be used, such as fiber optic communication paths and/or wireless communication paths.

VOLATILE MEMORY 112 is any type of volatile memory now known or to be developed in the future. Examples include dynamic type random access memory (RAM) or static type RAM. Typically, volatile memory 112 is characterized by random access, but this is not required unless affirmatively indicated. In computer 101, the volatile memory 112 is located in a single package and is internal to computer 101, but, alternatively or additionally, the volatile memory may be distributed over multiple packages and/or located externally with respect to computer 101.

PERSISTENT STORAGE 113 is any form of non-volatile storage for computers that is now known or to be developed in the future. The non-volatility of this storage means that the stored data is maintained regardless of whether power is being supplied to computer 101 and/or directly to persistent storage 113. Persistent storage 113 may be a read only memory (ROM), but typically at least a portion of the persistent storage allows writing of data, deletion of data and re-writing of data. Some familiar forms of persistent storage include magnetic disks and solid state storage devices. Operating system 122 may take several forms, such as various known proprietary operating systems or open source Portable Operating System Interface-type operating systems that employ a kernel. The code included in block 200 typically includes at least some of the computer code involved in performing the inventive methods.

PERIPHERAL DEVICE SET 114 includes the set of peripheral devices of computer 101. Data communication connections between the peripheral devices and the other components of computer 101 may be implemented in various ways, such as Bluetooth connections, Near-Field Communication (NFC) connections, connections made by cables (such as universal serial bus (USB) type cables), insertion-type connections (for example, secure digital (SD) card), connections made through local area communication networks and even connections made through wide area networks such as the internet. In various embodiments, UI device set 123 may include components such as a display screen, speaker, microphone, wearable devices (such as goggles and smart watches), keyboard, mouse, printer, touchpad, game controllers, and haptic devices. Storage 124 is external storage, such as an external hard drive, or insertable storage, such as an SD card. Storage 124 may be persistent and/or volatile. In some embodiments, storage 124 may take the form of a quantum computing storage device for storing data in the form of qubits. In embodiments where computer 101 is required to have a large amount of storage (for example, where computer 101 locally stores and manages a large database) then this storage may be provided by peripheral storage devices designed for storing very large amounts of data, such as a storage area network (SAN) that is shared by multiple, geographically distributed computers. IoT sensor set 125 is made up of sensors that can be used in Internet of Things applications. For example, one sensor may be a thermometer and another sensor may be a motion detector.

NETWORK MODULE 115 is the collection of computer software, hardware, and firmware that allows computer 101 to communicate with other computers through WAN 102. Network module 115 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 115 are performed on the same physical hardware device. In other embodiments (for example, embodiments that utilize software-defined networking (SDN)), the control functions and the forwarding functions of network module 115 are performed on physically separate devices, such that the control functions manage several different network hardware devices. Computer readable program instructions for performing the inventive methods can typically be downloaded to computer 101 from an external computer or external storage device through a network adapter card or network interface included in network module 115.

WAN 102 is any wide area network (for example, the internet) capable of communicating computer data over non-local distances by any technology for communicating computer data, now known or to be developed in the future. In some embodiments, the WAN 102 may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

END USER DEVICE (EUD) 103 is any computer system that is used and controlled by an end user (for example, a customer of an enterprise that operates computer 101), and may take any of the forms discussed above in connection with computer 101. EUD 103 typically receives helpful and useful data from the operations of computer 101. For example, in a hypothetical case where computer 101 is designed to provide a recommendation to an end user, this recommendation would typically be communicated from network module 115 of computer 101 through WAN 102 to EUD 103. In this way, EUD 103 can display, or otherwise present, the recommendation to an end user. In some embodiments, EUD 103 may be a client device, such as thin client, heavy client, mainframe computer, desktop computer and so on.

REMOTE SERVER 104 is any computer system that serves at least some data and/or functionality to computer 101. Remote server 104 may be controlled and used by the same entity that operates computer 101. Remote server 104 represents the machine(s) that collect and store helpful and useful data for use by other computers, such as computer 101. For example, in a hypothetical case where computer 101 is designed and programmed to provide a recommendation based on historical data, then this historical data may be provided to computer 101 from remote database 130 of remote server 104.

PUBLIC CLOUD 105 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 105 is performed by the computer hardware and/or software of cloud orchestration module 141. The computing resources provided by public cloud 105 are typically implemented by virtual computing environments that run on various computers making up the computers of host physical machine set 142, which is the universe of physical computers in and/or available to public cloud 105. The virtual computing environments (VCEs) typically take the form of virtual machines from virtual machine set 143 and/or containers from container set 144. It is understood that these VCEs may be stored as images and may be transferred among and between the various physical machine hosts, either as images or after instantiation of the VCE. Cloud orchestration module 141 manages the transfer and storage of images, deploys new instantiations of VCEs and manages active instantiations of VCE deployments. Gateway 140 is the collection of computer software, hardware, and firmware that allows public cloud 105 to communicate through WAN 102.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

PRIVATE CLOUD 106 is similar to public cloud 105, except that the computing resources are only available for use by a single enterprise. While private cloud 106 is depicted as being in communication with WAN 102, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 105 and private cloud 106 are both part of a larger hybrid cloud.

Exemplary Design Process Used in Semiconductor Design, Manufacture, and/or Test

One or more embodiments make use of computer-aided semiconductor integrated circuit design simulation, test, layout, and/or manufacture. In this regard, FIG. 15 shows a block diagram of an exemplary design flow 700 used for example, in semiconductor IC logic design, simulation, test, layout, and manufacture. Design flow 700 includes processes, machines and/or mechanisms for processing design structures or devices to generate logically or otherwise functionally equivalent representations of design structures and/or devices, such as those that can be analyzed using techniques disclosed herein or the like. The design structures processed and/or generated by design flow 700 may be encoded on machine-readable storage media to include data and/or instructions that when executed or otherwise processed on a data processing system generate a logically, structurally, mechanically, or otherwise functionally equivalent representation of hardware components, circuits, devices, or systems. Machines include, but are not limited to, any machine used in an IC design process, such as designing, manufacturing, or simulating a circuit, component, device, or system. For example, machines may include: lithography machines, machines and/or equipment for generating masks (e.g. e-beam writers), computers or equipment for simulating design structures, any apparatus used in the manufacturing or test process, or any machines for programming functionally equivalent representations of the design structures into any medium (e.g. a machine for programming a programmable gate array).

Design flow 700 may vary depending on the type of representation being designed. For example, a design flow 700 for building an application specific IC (ASIC) may differ from a design flow 700 for designing a standard component or from a design flow 700 for instantiating the design into a programmable array, for example a programmable gate array (PGA) or a field programmable gate array (FPGA) offered by Altera® Inc. or Xilinx® Inc.

FIG. 15 illustrates multiple such design structures including an input design structure 720 that is preferably processed by a design process 710. Design structure 720 may be a logical simulation design structure generated and processed by design process 710 to produce a logically equivalent functional representation of a hardware device. Design structure 720 may also or alternatively comprise data and/or program instructions that when processed by design process 710, generate a functional representation of the physical structure of a hardware device. Whether representing functional and/or structural design features, design structure 720 may be generated using electronic computer-aided design (ECAD) such as implemented by a core developer/designer. When encoded on a gate array or storage medium or the like, design structure 720 may be accessed and processed by one or more hardware and/or software modules within design process 710 to simulate or otherwise functionally represent an electronic component, circuit, electronic or logic module, apparatus, device, or system. As such, design structure 720 may comprise files or other data structures including human and/or machine-readable source code, compiled structures, and computer executable code structures that when processed by a design or simulation data processing system, functionally simulate or otherwise represent circuits or other levels of hardware logic design. Such data structures may include hardware-description language (HDL) design entities or other data structures conforming to and/or compatible with lower-level HDL design languages such as Verilog and VHDL, and/or higher level design languages such as C or C++.

Design process 710 preferably employs and incorporates hardware and/or software modules for synthesizing, translating, or otherwise processing a design/simulation functional equivalent of components, circuits, devices, or logic structures to generate a Netlist 780 which may contain design structures such as design structure 720. Netlist 780 may comprise, for example, compiled or otherwise processed data structures representing a list of wires, discrete components, logic gates, control circuits, I/O devices, models, etc. that describes the connections to other elements and circuits in an integrated circuit design. Netlist 780 may be synthesized using an iterative process in which netlist 780 is resynthesized one or more times depending on design specifications and parameters for the device. As with other design structure types described herein, netlist 780 may be recorded on a machine-readable data storage medium or programmed into a programmable gate array. The medium may be a nonvolatile storage medium such as a magnetic or optical disk drive, a programmable gate array, a compact flash, or other flash memory. Additionally, or in the alternative, the medium may be a system or cache memory, buffer space, or other suitable memory.

Design process 710 may include hardware and software modules for processing a variety of input data structure types including Netlist 780. Such data structure types may reside, for example, within library elements 730 and include a set of commonly used elements, circuits, and devices, including models, layouts, and symbolic representations, for a given manufacturing technology (e.g., different technology nodes, 32 nm, 45 nm, 90 nm, etc.). The data structure types may further include design specifications 740, characterization data 750, verification data 760, design rules 770, and test data files 785 which may include input test patterns, output test results, and other testing information. Design process 710 may further include, for example, standard mechanical design processes such as stress analysis, thermal analysis, mechanical event simulation, process simulation for operations such as casting, molding, and die press forming, etc. One of ordinary skill in the art of mechanical design can appreciate the extent of possible mechanical design tools and applications used in design process 710 without deviating from the scope and spirit of the invention. Design process 710 may also include modules for performing standard circuit design processes such as timing analysis, verification, design rule checking, place and route operations, etc.

Design process 710 employs and incorporates logic and physical design tools such as HDL compilers and simulation model build tools to process design structure 720 together with some or all of the depicted supporting data structures along with any additional mechanical design or data (if applicable), to generate a second design structure 790. Design structure 790 resides on a storage medium or programmable gate array in a data format used for the exchange of data of mechanical devices and structures (e.g. information stored in an IGES, DXF, Parasolid XT, JT, DRG, or any other suitable format for storing or rendering such mechanical design structures). Similar to design structure 720, design structure 790 preferably comprises one or more files, data structures, or other computer-encoded data or instructions that reside on data storage media and that when processed by an ECAD system generate a logically or otherwise functionally equivalent form of one or more IC designs or the like. In one embodiment, design structure 790 may comprise a compiled, executable HDL simulation model that functionally simulates the devices to be analyzed.

Design structure 790 may also employ a data format used for the exchange of layout data of integrated circuits and/or symbolic data format (e.g. information stored in a GDSII (GDS2), GL1, OASIS, map files, or any other suitable format for storing such design data structures). Design structure 790 may comprise information such as, for example, symbolic data, map files, test data files, design content files, manufacturing data, layout parameters, wires, levels of metal, vias, shapes, data for routing through the manufacturing line, and any other data required by a manufacturer or other designer/developer to produce a device or structure as described herein (e.g., lib files). Design structure 790 may then proceed to a stage 795 where, for example, design structure 790: proceeds to tape-out, is released to manufacturing, is released to a mask house, is sent to another design house, is sent back to the customer, etc.

The illustrations of embodiments described herein are intended to provide a general understanding of the various embodiments, and they are not intended to serve as a complete description of all the elements and features of apparatus and systems that might make use of the circuits and techniques described herein. Many other embodiments will become apparent to those skilled in the art given the teachings herein; other embodiments are utilized and derived therefrom, such that structural and logical substitutions and changes can be made without departing from the scope of this disclosure. It should also be noted that, in some alternative implementations, some of the steps of the exemplary methods may occur out of the order noted in the figures. For example, two steps shown in succession may, in fact, be executed substantially concurrently, or certain steps may sometimes be executed in the reverse order, depending upon the functionality involved. The drawings are also merely representational and are not drawn to scale. Accordingly, the specification and drawings are to be regarded in an illustrative rather than a restrictive sense.

Embodiments are referred to herein, individually and/or collectively, by the term “embodiment” merely for convenience and without intending to limit the scope of this application to any single embodiment or inventive concept if more than one is, in fact, shown. Thus, although specific embodiments have been illustrated and described herein, it should be understood that an arrangement achieving the same purpose can be substituted for the specific embodiment(s) shown; that is, this disclosure is intended to cover any and all adaptations or variations of various embodiments. Combinations of the above embodiments, and other embodiments not specifically described herein, will become apparent to those of skill in the art given the teachings herein.

The terminology used herein is for the purpose of describing particular embodiments only and is not intended to be limiting. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, steps, operations, elements, and/or components, but do not preclude the presence or addition of one or more other features, steps, operations, elements, components, and/or groups thereof. Terms such as “bottom”, “top”, “above”, “over”, “under” and “below” are used to indicate relative positioning of elements or structures to each other as opposed to relative elevation. If a layer of a structure is described herein as “over” another layer, it will be understood that there may or may not be intermediate elements or layers between the two specified layers. If a layer is described as “directly on” another layer, direct contact of the two layers is indicated. As the term is used herein and in the appended claims, “about” means within plus or minus ten percent.

The corresponding structures, materials, acts, and equivalents of any means or step-plus-function elements in the claims below are intended to include any structure, material, or act for performing the function in combination with other claimed elements as specifically claimed. The description of the various embodiments has been presented for purposes of illustration and description, but is not intended to be exhaustive or limited to the forms disclosed. Many modifications and variations will be apparent to those of ordinary skill in the art without departing from the scope and spirit thereof. The embodiments were chosen and described in order to best explain principles and practical applications, and to enable others of ordinary skill in the art to understand the various embodiments with various modifications as are suited to the particular use contemplated.

The abstract is provided to comply with 37 C.F.R. § 1.76 (b), which requires an abstract that will allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in a single embodiment for the purpose of streamlining the disclosure. This method of disclosure is not to be interpreted as reflecting an intention that the claimed embodiments require more features than are expressly recited in each claim. Rather, as the appended claims reflect, the claimed subject matter may lie in less than all features of a single embodiment. Thus, the following claims are hereby incorporated into the Detailed Description, with each claim standing on its own as separately claimed subject matter.

Given the teachings provided herein, one of ordinary skill in the art will be able to contemplate other implementations and applications of the techniques and disclosed embodiments. Although illustrative embodiments have been described herein with reference to the accompanying drawings, it is to be understood that illustrative embodiments are not limited to those precise embodiments, and that various other changes and modifications are made therein by one skilled in the art without departing from the scope of the appended claims.

What is claimed is:

1. A magnetoresistive random-access memory cell, comprising:
a substrate;
a seed layer outward of the substrate;
a resistive layer outward of the seed layer;
an ultra-thin templating layer, outward of the resistive layer, comprising a binary alloy having an alternating layer lattice structure, the ultra-thin templating layer having a thickness of 7-30 Angstroms; and
a Heusler layer located outward of the ultra-thin templating layer, the Heusler layer comprising a Heusler compound and exhibiting perpendicular magnetic anisotropy (PMA).

2. The magnetoresistive random-access memory cell of claim 1, wherein the Heusler layer is located directly on the ultra-thin templating layer and the ultra-thin templating layer is located directly on the resistive layer.

3. The magnetoresistive random-access memory cell of claim 2, further comprising a nitride layer, outward of the substrate, and having a nitride layer thickness less than 20 Angstroms.

4. The magnetoresistive random-access memory cell of claim 3, wherein the nitride layer comprises a sub-monolayer nitride layer.

5. The magnetoresistive random-access memory cell of claim 3, wherein the sub-monolayer nitride layer is formed with at least one of Mn, Sc, Ti, Cr, and V.

6. The magnetoresistive random-access memory cell of claim 3, further comprising:
a tunnel barrier outward of the Heusler layer; and
a magnetic layer outward of the tunnel barrier.

7. The magnetoresistive random-access memory cell of claim 6, wherein:
the Heusler layer comprises a storage layer; and
the magnetic layer comprises a reference layer.

8. The magnetoresistive random-access memory cell of claim 7, wherein the Heusler compound is selected from the group consisting of Mn₃Ge, Mn₃Sn, Mn₃Sb, Mn₂CoSn, Mn₂FeSb, Mn₂CoAl, Mn₂CoGe, Mn₂CoSi, Mn₂CuSi, Co₂CrAl, Co₂CrSi, Co₂MnSb, and Co₂MnSi.

9. The magnetoresistive random-access memory cell of claim 8, wherein the Heusler compound comprises Mn₃Ge.

10. The magnetoresistive random-access memory cell of claim 7, wherein the Heusler layer has a thickness of less than 5 nm.

11. The magnetoresistive random-access memory cell of claim 7, wherein the tunnel barrier is in contact with the Heusler layer.

12. The magnetoresistive random-access memory cell of claim 11, wherein the tunnel barrier is selected from the group consisting of magnesium oxide and magnesium aluminum oxide.

13. The magnetoresistive random-access memory cell of claim 12, wherein the tunnel barrier comprises magnesium oxide.

14. The magnetoresistive random-access memory cell of claim 12, wherein the tunnel barrier comprises Mg_{1-z}Al_{2+(2/3)z}O₄, wherein −0.5<z<0.5.

15. The magnetoresistive random-access memory cell of claim 7, wherein the binary alloy is represented by A₁₋ₓEₓ, wherein A is a transition metal element and E is a main group element including at least one of aluminum and gallium, and x is in the range from 0.42 to 0.55.

16. The magnetoresistive random-access memory cell of claim 7, wherein the alternating layer lattice structure of the ultra-thin templating layer comprises a cesium chloride structure.

17. The magnetoresistive random-access memory cell of claim 16, wherein the ultra-thin templating layer comprises CoAl with a thickness of from 7 to 10 Angstroms.

18. The magnetoresistive random-access memory cell of claim 7, wherein the resistive layer comprises ScₓN.

19. The magnetoresistive random-access memory cell of claim 18, wherein the resistive layer has a thickness of 10-250 Angstroms.

20. The magnetoresistive random-access memory cell of claim 19, wherein the resistive layer has a thickness of 20-100 Angstroms.

21. A magnetoresistive random-access memory array, comprising:
a plurality of bit lines and a plurality of complementary bit lines forming a plurality of bit line-complementary bit line pairs;
a plurality of word lines intersecting the plurality of bit line pairs at a plurality of cell locations;
a plurality of magnetoresistive random-access memory cells located at each of the plurality of cell locations, each of the magnetoresistive random-access memory cells being electrically connected to a corresponding bit line and selectively interconnected to a corresponding one of the complementary bit lines under control of a corresponding one of the word lines, each of the plurality of magnetoresistive random-access memory cells comprising:
a substrate;
a seed layer outward of the substrate;
a resistive layer outward of the seed layer;
an ultra-thin templating layer, outward of the resistive layer, comprising a binary alloy having an alternating layer lattice structure, the ultra-thin templating layer having a thickness of 7-30 Angstroms; and
a Heusler layer located outward of the ultra-thin templating layer, the Heusler layer comprising a Heusler compound and exhibiting perpendicular magnetic anisotropy (PMA).

22. The magnetoresistive random-access memory array of claim 21, wherein the Heusler layer is located directly on the ultra-thin templating layer and the ultra-thin templating layer is located directly on the resistive layer.

23. The magnetoresistive random-access memory array of claim 22, further comprising a nitride layer, outward of the substrate, and having a nitride layer thickness less than 20 Angstroms.

24. A method of forming a magnetoresistive random-access memory cell, comprising:
providing a substrate;
forming a nitride layer, outward of the substrate, and having a nitride layer thickness less than 20 Angstroms;
providing a seed layer outward of the nitride layer;
providing a resistive layer outward of the seed layer;
providing an ultra-thin templating layer, outward of the resistive layer, and comprising a binary alloy having an alternating layer lattice structure;
epitaxially growing a Heusler layer located outward of the ultra-thin templating layer, the Heusler layer comprising a Heusler compound and exhibiting perpendicular magnetic anisotropy (PMA);
forming a tunnel barrier outward of the Heusler layer; and
forming a magnetic layer outward of the tunnel barrier.

25. A hardware description language (HDL) design structure encoded on a machine-readable data storage medium, the HDL design structure comprising elements that when processed in a computer-aided design system generates a machine-executable representation of a magnetoresistive random-access memory cell, wherein the (HDL design structure) comprises:
a substrate;
a seed layer outward of the substrate;
a resistive layer outward of the seed layer;
an ultra-thin templating layer, outward of the resistive layer, comprising a binary alloy having an alternating layer lattice structure, the ultra-thin templating layer having a thickness of 7-30 Angstroms; and
a Heusler layer located outward of the ultra-thin templating layer, the Heusler layer comprising a Heusler compound and exhibiting perpendicular magnetic anisotropy (PMA).
